(19) United States
(12) Patent Application Publication
(10) Pub. No.: US 2005/0221574 A1
(43) Pub. Date: Oct. 6, 2005

(54) Method for fabricating semiconductor device

(75) Inventors: Myung-Kyu Ahn, Ichon-shi (KR); Yun-Seok Cho, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Kyoungki-do (KR)

(21) Appl. No.: 11/095,028

(22) Filed: Mar. 30, 2005

(30) Foreign Application Priority Data
Mar. 31, 2004 (KR) 2004-22061
Mar. 7, 2005 (KR) 2005-18756

(51) Int. Cl. H01L 21/20; H01L 29/00; H01L 21/44

(52) U.S. Cl. 438/386; 438/672

(57) ABSTRACT

The present invention relates to a method for fabricating a semiconductor device with a capacitor by performing a plasma blanket etch-back process without employing a supplemental layer for isolating lower electrodes. The method includes the steps of: forming an insulation layer with a plurality of openings on a substrate to form lower electrodes; forming a conductive layer on the insulation layer; and etching first portions of the conductive layer formed outside the openings in a faster rate than second portions of the conductive layer formed inside the openings, thereby isolating the lower electrodes from each other.

### CROSS-REFERENCES TO RELATED APPLICATIONS

The present application contains subject matter related to the Korean patent application Nos. KR 2004-0022061 and 2005-0018756, filed in the Korean Patent Office on Mar. 31, 2004 and Mar. 7, 2005, respectively, the entire contents of which being incorporated herein by reference.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

1. Field of the Invention

The present invention relates to a method for fabricating a semiconductor device; and, more particularly, to a method for fabricating a semiconductor device with a capacitor.

2. Description of Related Arts

An increase in the scale of integration and a decrease in the minimum line width of a semiconductor device have led to a decrease in capacitor area. As a result of this decreasing capacitor area, it is mandated for a capacitor to have a capacitance greater than about 25 fF minimally required for each cell. Therefore, various approaches to fabricate a capacitor with a high capacitance in a limited area have been attempted. One approach is to use a dielectric material having a high dielectric constant such as tantalum oxide (Ta₂O₅), aluminum oxide (Al₂O₃) or hafnium oxide (HfO₂) instead of employing silicon oxide having a dielectric constant of 3.8 and nitride having a dielectric constant of 7. Another approach is to form a lower electrode of a capacitor in three-dimensional shapes such as a cylinder shape or a concave shape so as to increase the area of the lower electrode. A further approach is to increase the effective surface area of the lower electrode by about 1.7 to 2 times more than the original one by growing metastable polysilicon (MPS) grains on the surface of the lower electrode.

When a cylinder or concave type of a capacitor is fabricated, it is essential to perform a lower electrode isolation process which utilizes a chemical mechanical polishing process or a plasma blanket etch-back process.

FIGS. 1A to 1D are cross-sectional views illustrating a conventional method for isolating lower electrodes with use of a plasma blanket etch-back process.

Referring to FIG. 1A, a plurality of junction regions 12 such as sources and drains of transistors are formed in predetermined regions of a substrate 11. Herein, although not illustrated, prior to forming the junction regions 12, a field oxide layer for device isolation is formed, and then gate structures are formed on the substrate 11.

Next, an inter-layer insulation layer 13 is formed on the substrate 11. Although not illustrated, prior to forming the inter-layer insulation layer 13, an inter-layer insulation layer formation process for covering the gate structures with another inter-layer insulation layer and a bit line formation process are performed. Therefore, the inter-layer insulation layer 13 has a multi-layered structure.

Afterwards, the inter-layer insulation layer 13 is etched to form a plurality of storage node contact holes 14 each exposing the junction regions 12. Then, a plurality of storage node contact plugs 15 are filled into the storage node contact holes 14. Herein, the storage node contact plugs 15 serve a role in enabling signal processing between capacitors and the transistors.

An etch barrier layer 16 and an insulation layer 17 for forming a capacitor structure are sequentially formed on the inter-layer insulation layer 13 and the storage node contact plugs 15. Then, the etch barrier layer 16 and the insulation layer 17 are sequentially etched to form a plurality of openings 18 exposing the storage node contact plugs 15.

After the formation of openings 18, a conductive layer for use in a lower electrode, for instance, a polysilicon layer 19 is formed on the insulation layer 17 and into each of the openings 18. Thereafter, a lower electrode isolation process is carried out, and a photoresist layer 20 acting as a supplemental layer for the lower electrode isolation is formed on the polysilicon layer 19.

Referring to FIG. 1B, a portion of the photoresist layer 20 is removed by a plasma blanket etch-back process, so that the photoresist layer 20 remains only inside of the openings 18.

Referring to FIG. 1C, portions of the polysilicon layer 19 disposed on the insulation layer 17 are removed by performing the plasma blanket etch-back process, so that cylindrical lower electrodes 19A are formed inside of the openings 18.

Referring to FIG. 1D, a stripping process for removing the photoresist layer 20 is carried out by using oxygen plasma, and then, the insulation layer 17 is removed to thereby expose the cylindrical lower electrodes 19A.

As described above, the photoresist layer 20 is used as the supplemental layer for isolating the lower electrodes 19A in order to prevent the interior sides of the capacitors from being damaged during the lower electrode isolation process and to prevent a contamination problem occurring when a subsequent process for increasing surface areas of the lower electrodes 19A is applied. Also, with use of the oxygen plasma, the photoresist layer 20 can be easily removed without damaging the lower electrodes 19A.

However, in the case of employing the plasma blanket etch-back process for the lower electrode isolation, it is necessary to perform at least four additional steps; forming the supplemental layer for isolating the lower electrodes, removing portions of the supplemental layer, completely removing the supplemental layer and performing a cleaning process. Furthermore, it is difficult to completely remove the supplemental layer in a sub-100 nm nanotechnology. For instance, when the photoresist layer is used as the supplemental layer, the photoresist layer may still remain on certain regions of a wafer during the step of removing the supplemental layer carried out after the plasma blanket etch-back process, and this remaining photoresist layer may induce an incidence of single bit failure. This problem may be observed when metals such as titanium nitride (TiN) and ruthenium (Ru) are employed as a conductive layer used for forming lower electro

### BRIEF SUMMARY OF THE INVENTION

It is, therefore, an object of the present invention to provide a method for fabricating a semiconductor device capable of proceeding with a simple lower electrode isolation process without damaging lower electrodes and preventing an incidence of single bit failure occurring when a supplemental layer for the lower electrode isolation is used.

In accordance with an aspect of the present invention, a method for fabricating a semiconductor device is provided, including the steps of: (a) forming an insulation layer with a plurality of openings on a substrate to form lower electrodes; (b) forming a conductive layer on the insulation layer; and (c) etching first portions of the conductive layer formed outside the openings in a faster rate than second portions of the conductive layer formed inside the openings, thereby isolating the lower electrodes from each other.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1D are cross-sectional views illustrating a conventional method for isolating lower electrodes by employing a plasma blanket etch-back process; and

FIGS. 2A to 2D are cross-sectional views illustrating a method for fabricating a semiconductor device in accordance with a preferred embodiment of the present invention.

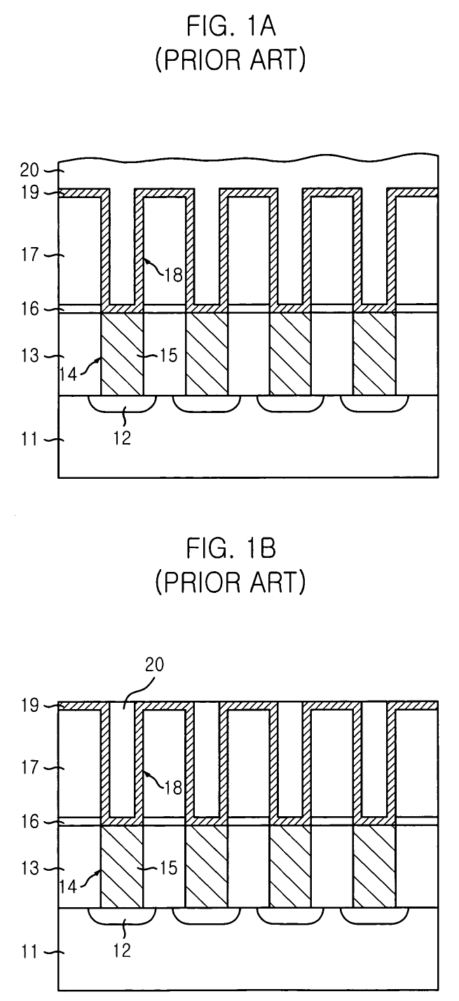

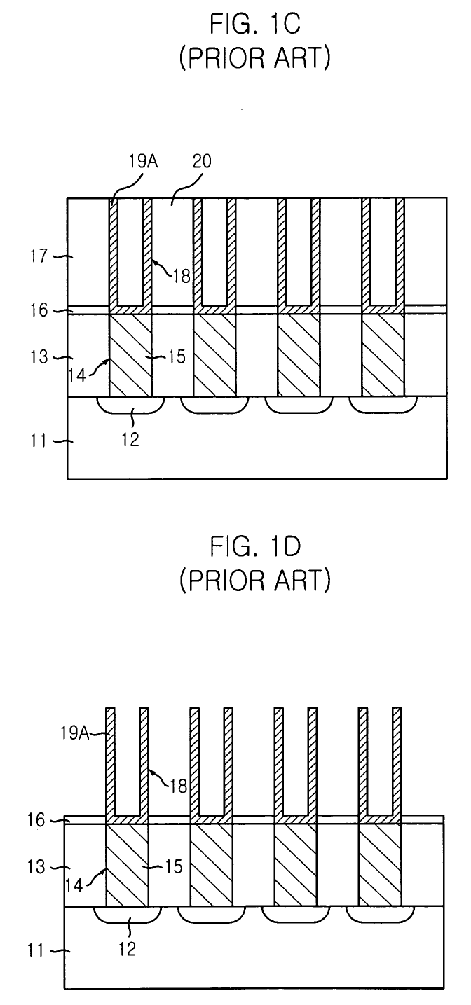

### DETAILED DESCRIPTION OF THE INVENTION

A method for fabricating a semiconductor device in accordance with a preferred embodiment of the present invention will be described in detail with reference to the accompanying drawings, which is set forth hereinafter.

In order to simplify a lower electrode isolation process which becomes complicated when using a supplemental layer such as a photoresist layer for preventing inner sides and bottom surfaces of lower electrodes from being damaged during the lower electrode isolation process, the preferred embodiment of the present invention is exemplified in the case of employing a plasma blanket etch-back process for isolating the lower electrodes without damaging the lower electrodes even in the absence of the supplemental layer.

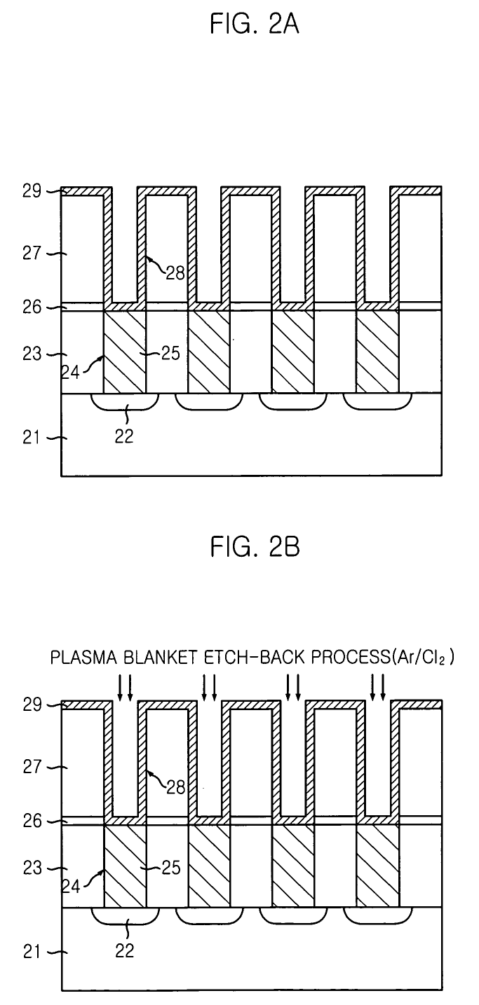

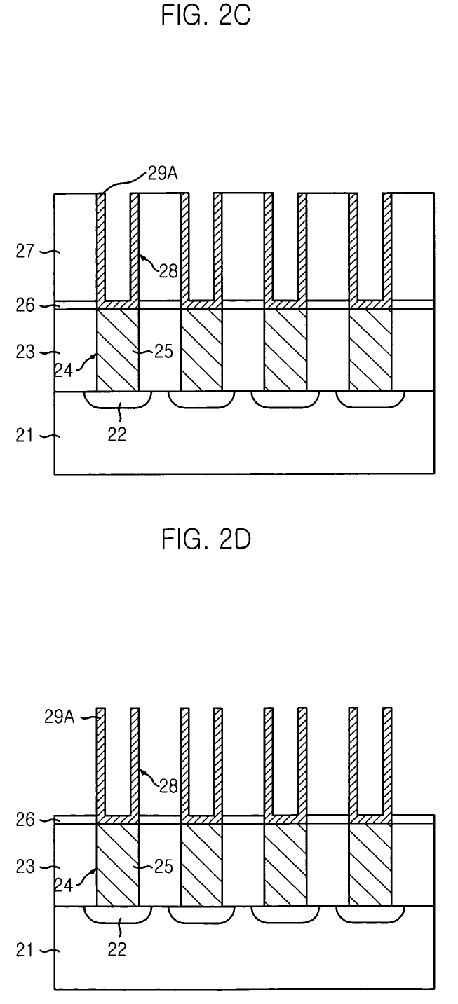

FIGS. 2A to 2D are cross-sectional views illustrating a method for fabricating a semiconductor device with a capacitor in accordance with the preferred embodiment of the present invention.

Referring to FIG. 2A, a number of junction regions 22 such as sources/drains of transistors are formed in a substrate 21. Although not illustrated, prior to forming the junction regions 22, a field oxide layer for device isolation is formed, and a number of gate structures are formed on the substrate 21.

After the formation of the junction regions 22, an inter-layer insulation layer 23 is formed on the substrate 21. Although not illustrated, prior to forming the inter-layer insulation layer 23, another inter-layer insulation layer for covering the gate structures is formed and then, etched to form bit lines. Therefore, the inter-layer insulation layer 23 has a multi-layered structure.

Next, the inter-layer insulation layer 23 is etched to form storage node contact holes 24 exposing the respective junction regions 22, and a plug material is filled into the storage node contact holes 24, thereby forming a number of storage node contact plugs 25. Herein, the storage node contact plugs 25 filled into the storage node contact holes 24 serve a role in enabling signal processing between capacitors, which will be formed subsequently, and the transistors.

Afterwards, an etch barrier layer 26 and an insulation layer 27 for forming a capacitor structure are sequentially formed on the inter-layer insulation layer 23 and the storage node contact plugs 25. Then, the insulation layer 27 and the etch barrier layer 26 are sequentially etched to form a number of openings 28 exposing the respective storage node contact plugs 25.

A conductive layer 29 to form lower electrodes is formed on the insulation layer 27 and into the openings 28. Herein, the conductive layer 29 is based on a material selected from a group consisting of doped polysilicon, a stack of undoped polysilicon/doped polysilicon, tungsten (W), titanium nitride (TiN), ruthenium (Ru), and platinum (Pt).

Referring to FIG. 2B, a lower electrode isolation process is carried out. At this time, in order to form cylindrical lower electrodes, a plasma blanket etch-back process is performed without employing a photoresist layer, which is a supplemental layer for the lower electrode isolation used in the conventional method. Also, depending on an employed material for forming the conductive layer 29, the etch process recipe becomes different.

Hereinafter, assuming that the conductive layer 29 for forming the lower electrodes is based on one selected material of TiN, the plasma blanket etch-back process will be described in detail.

Generally, a plasma etching apparatus is comprised of a chamber with a top electrode and a bottom electrode. A wafer with a target etch structure is disposed on top of the bottom electrode. Herein, the top electrode is an electrode for supplying a source power to generate a plasma, while the bottom electrode is an electrode for supplying a bias power to attract ions and radicals of the plasma toward the wafer. Since the top electrode and the bottom electrode are separated from each other, it is possible to control the energy of the ions and the radicals separately.

The plasma etch-back process carried out by employing the above mentioned plasma etching apparatus can be classified into a physical etching process, a chemical etching process and a physicochemical etching process.

First, in the physical etching process, a plasma is generated by using an inert gas such as argon (Ar), helium (He) and xenon (Xe). The positive ions of the plasma perpendicularly hit the wafer, thereby physically etching an etch target layer. On the other hand, the chemical etching process produces an etching of the etch target layer by generating a plasma with use of a gas that is chemically reactive to the etch target layer in a plasma phase and then chemically etching the etch target layer through the use of activated neutral radicals of the plasma. The physicochemical etching process produces an etching by using the strong collision energy of positive ions created as the positive ions of the plasma hit the wafer and concurrently radicals of the plasma, which is chemically reactive to the etch target layer. As a result of these characteristics of the physicochemical etching process, it is possible to obtain a synergistic effect of increasing the etch rate by one step faster.

On the basis of the above described principles of the plasma etching process, when the conductive layer 29, i.e., the TiN layer, is etched, a mixed gas of Ar and Cl₂ gases is used to induce a physicochemical etching of the TiN layer 29. That is, the Ar gas is for a physical etching of the TiN layer 29, while the Cl₂ gas is for a chemical etching of the TiN layer 29 based on the fact that Cl₂ gas is chemically reactive to TiN.

Under the assumption that the physical etching process is solely carried out by using the Ar gas, when the TiN layer 29 is subjected to the plasma blanket etch-back process without employing a supplemental layer for forming the lower electrodes, the TiN layer 29 formed outside the openings 28 and that formed inside the openings 28 are etched. Also, TiN molecules bumped out during the physical etching process become continuously deposited on the walls of the etch chamber, as a result, there are problems in that efficiency on power transmission is reduced and undesired particles are generated.

If the chemical etching process is solely carried out by using the Cl₂ gas for forming the lower electrodes without using the supplemental layer, an isotropic etching characteristic, i.e., having no directionality, is observed in the chemical etching process. Thus, portions of the TiN layer 29 disposed outside the openings 28 as well as on the deep region of the inner side of each opening 28 are etched and thus, the height of the lower electrodes decreases. Also, the TiN layer 29 is etched as the Cl₂ gas is diffused along grains of the TiN layer 29, thereby resulting in roughness and non-uniform shape of the lower electrodes. Furthermore, the grains of the TiN layer 29 are easily broken off even by a weak shock, resulting in defects in devices. In addition, if the aspect ratio of an etch profile of the insulation layer 27 is small, the TiN layer 29 disposed on the bottom part of the inner side of each opening 28 is etched, resulting in a complete etching of the lower electrodes.

Accordingly, to achieve an intended isolation of the lower electrodes without using the supplemental layer, the TiN layer 29 formed outside the openings 28 is set to be etched in a faster rate by applying the physical etching process and the chemical etching process simultaneously. Meanwhile, the TiN layer 29 formed inside the individual openings 28, more particularly, formed on the bottom part and lateral parts of the inner side of each opening 28, is set to be chemically etched in a slow rate by controlling the etch gas and the etch recipe.

Generally, in the case of etching polysilicon and metal, the physical etching process take place scarcely at the inner lateral parts of each opening 28 because of the directionality of the ions. However, at the inner bottom part of each opening 28, the physical etching process takes place. To suppress the physical etching process from taking place at the inner bottom part of each opening 28, the internal pressure of each opening 28 is increased to cause a loss of energy in ions getting into the individual openings 28 in a perpendicular direction by inducing collisions of the ions with other particles existing inside of the individual openings 28. The internal pressure of the individual openings 28 can be increased by applying a plasma etching process with use of an etch gas that is capable of inducing a chemical etching with respect to the lower electrode material formed inside the individual openings 28.

At this time, when large amounts of the lower electrode material disposed inside the individual openings 28 and etch remnants generated during the chemical etching exist, the internal pressure of each opening 28 can be increased and as a result, the ions getting into the inner side of each opening 28 collide with the etch remnants, causing a loss of energy of the ions. Thus, even if the ions arrive at the inner bottom part of each opening 28, the energy decrease is great enough to block the physical etching process from taking place.

In addition to the increase in the internal pressure of the openings 28, it is necessary to decrease the energy level of the ions getting into the inner side of each opening 28 to minimize or eliminate the effect of the physical etching process on the inner bottom part of each opening 28. That is, even if the internal pressure of the individual openings 28 is high, the physical etching can take place at the inner bottom part of the individual openings 28 if the energy level of the ions is still high. Therefore, the ion energy level around the inner bottom part of each opening 28 is determined by combining the internal pressure of the individual openings 28 caused by the etch remnants and a bias power that determines the ion energy level.

For adjustment of the internal pressure of the individual openings 28 caused by etch remnants, that is, the adjustment of an amount of etch remnants generated during the chemical etching process, it is important to select an appropriate etch gas that induces the chemical etching and adjust a composition ratio between an etch gas for the physical etching process and an etch gas for the chemical etching process. Also, it is preferable to decrease the ion energy as much as possible for minimizing the ion energy level around the inner bottom part of the individual openings 28. However, if the bias power decreases to an extremely low level for the purpose of suppressing the physical etching process from taking place, the TiN layer 29 formed outside the openings 28 may not be physically etched. For this reason, the bias power should be set appropriately.

In summary, the plasma blanket etch-back process carried out without using the supplemental layer requires an appropriate etch recipe and combination of etch gases that make a portion of the lower electrode material formed outside the individual openings 28 etched chemically and physically while another portion of the lower electrode material formed on the inner lateral and bottom parts of the individual openings 28 etched chemically.

For instance, in case of TiN, a mixed gas of Ar and Cl₂ is used to give rise to a physicochemical etching process at the outer side of the individual openings 28, and a bias power is adjusted to a low level ranging from approximately 30 W to approximately 300 W for the purpose of suppressing the physical etching process from taking place at the inner bottom part of the individual openings 28. Also, the composition percentage of the Cl₂ gas in the mixed gas of Ar and Cl₂ gases is adjusted to be in a range from approximately 1% to approximately 50% to control a degree of the chemical etching process.

Further, the pressure of the etch chamber is controlled to be in a range from approximately 1 mtorr to approximately 50 mtorr in order to make the physical etching and the chemical etching performed in intended degrees. Additionally, the power of the top electrode, the chamber pressure, the temperature of the top electrode, and the chamber temperature do not have a great influence on the plasma blanket etch-back process, but are adjusted to be appropriately applied to each required process recipe.

In case that the plasma blanket etch-back process is carried out under the above described process recipe, the TiN layer 29 disposed outside the individual openings 28 is etched in a faster rate, whereas the TiN layer 29 disposed on the inner lateral parts of the individual opening 28 is minimally etched since the chemical etching of the TiN layer 29 disposed on the inner lateral parts of the individual openings 28 is set to be carried out in a slow rate by adjusting the composition percentage of the Cl₂ gas to be in a range from approximately 1% to 50%.

Also, as byproducts of a reaction between the radicals and the TiN layer 29 formed on the inner lateral parts of the individual openings 28 fill the openings 28, the internal pressure of each opening 28 increases and the bias power is adjusted to be in a low range from approximately 30 W to approximately 300 W. Thus, the radicals of the plasma that are diffusing towards the inner bottom part of the individual openings 28 and the positive ions of the plasma getting into the inner bottom part of the individual openings 28 are suppressed from flowing inside and as a result, the TiN layer 29 formed on the inner bottom part of each opening 28 is less etched.

On the whole, the process mentioned above is set to make the TiN layer 29 formed outside the individual openings 28 etched rapidly by the physicochemical etching process and to make the TiN layer 29 disposed on the inner lateral parts and the inner bottom part of the individual openings 28 etched in a slower rate than the TiN layer 29 formed outside the individual openings 28, and thus, even if the plasma blanket etch-back process is performed in a perpendicular direction without using the supplemental layer, it is still possible to obtain an intended etch profile of the lower electrodes.

When the plasma blanket etch-back process is carried out with respect to the TiN layer 29, the etch rate at the inner lateral and bottom parts of the individual openings 28 is adjusted to be in a range from approximately 1% to approximately 70% in comparison with that at the outer side of the individual openings 28. Also, the etch rate at the inner lateral parts of the individual openings 28 is adjusted to be identical to that at the inner bottom part of the individual openings 28.

For such intended etch rates, a specific recipe is set. First, a chamber pressure and a chamber temperature are maintained at approximately 10 mtorr and 40° C., respectively. Also, a source power of approximately 300 W and a bias power of approximately 100 are supplied. At this time, approximately 10 sccm of Cl₂ gas and approximately 190 sccm of Ar gas are provided. Additionally, the end of point (EOP) and the over-etching (OE) are approximately 16″±1″ and 10″, respectively.

Under the above predetermined recipe, when the thickness of the TiN layer 29 is assumed to be approximately 30 Å, an etch rate at the outer side of the individual openings 28 is approximately 1,120 Å per minute, and an etch rate at the inner lateral parts and the inner bottom part of the individual openings 28 decreases in a greater extent by being approximately 10 Å per minute. Herein, the etch rate of the TiN layer 29 at the outer side of the individual openings 28 varies depending on an etch recipe, an average value of the etch rate is in a range from approximately 500 Å per minute to approximately 2,000 Å per minute. Thus, an average etch rate of the TiN layer 29 at the inner lateral and bottom parts of the individual openings 28 ranges from approximately 5 Å per minute to approximately 140 Å per minute. The latter etch rate is approximately 7% of the formal etch rate which is approximately 2,000 Å per minute.

Furthermore, the etch rate, that is changeable by composition ratio adjustment of the Cl₂ gas and the Ar gas, is more than approximately 500 Å per minute when the composition ratio of the Cl₂ gas to the Ar gas is very low. On the other hand, when the composition ratio of the Cl₂ gas to the Ar gas is very high, the etch rate changes to approximately 3,000 Å per minute. That is, the etch rate can be changeable within a range from approximately 500 Å per minute to approximately 3,000 Å per minute through adjusting the composition ratio between the Cl₂ gas and the Ar gas. However, since the lower electrodes are not thick, throughput is not an issue. Nevertheless, the etch recipe is adjusted to slow down the etch rate for the purpose of controlling the etch profile, over-etching and the like.

Preferably, the plasma blanket etch-back process proceeds at a pressure of approximately 5 mtorr to approximately 20 mtorr, a source power of approximately 300 W to approximately 800 W and a bias power of approximately 30 W to approximately 300 W. At this time, the percentage of the Cl₂ gas with respect to the mixed gas of Ar and Cl₂ gases is preferably in a range from approximately 1% to approximately 50%, and an electrode temperature preferably in a range from approximately 10° C. to approximately 40° C.

In the above preferred embodiment of the present invention, an etch gas that induces the chemical etching process during the plasma blanket etch-back process on the TiN layer 29 can be a single Chlorine-based gas selected from a group consisting of Cl₂, HCl and CCl₄ or a gas obtained by mixing the above listed chlorine-based gases in combination. In addition to the use of this mentioned mixed gas, a gas such as Ar, Xe and He can be added singly or in combination to stabilize the plasma, control quantities of the target gases and dilute the etch gas. Furthermore, it is possible to add one or both O₂ gas and N₂ gas for the passivation purpose or as a reaction inhibitor for the purpose of preventing the lower electrodes from being damaged by the dominantly performed chemical etching process.

Although the preferred embodiment of the present invention exemplifies the etch recipe when the TiN is used for the lower electrodes, the etch recipe varies depending on the material used for the conductive layer 29.

First, in case that a silicon-based material is used as the conductive layer 29 for forming the lower electrodes, an etch gas for the chemical etching process of the plasma blanket etch-back process is selected singly or in combination from a group consisting of a fluorine-based gas such as SF₆, NF₃ or CF₄, a chlorine-based gas such as Cl₂ and a bromine-based gas such as HBr.

In case of employing tungsten (W) as the conductive layer 29 for forming the lower electrodes, the etch gas for the chemical etching process of the plasma blanket etch-back process is selected singly or in combination from a group of fluorine-based gases consisting of SF₆, NF₃ and CF₄.

If a noble metal such as ruthenium (Ru) or platinum (Pt) is used as the conductive layer 29 for forming the lower electrodes, O₂ gas and Cl₂ gas selected singly or in combination are used as the etch gas for the chemical etching process of the plasma blanket etch-back process.

When performing the plasma blanket etch-back process using one of a silicon-based material, tungsten and a noble metal, an inert gas is used as an etch gas for the physical etching process in addition to the above descried etch gas for the chemical etching process. Also, an inert gas selected singly or in combination from a group consisting of Ar, Xe and He is used to stabilize the plasma, control quantities of selected gases and dilute the main etch gas. If chemical etching characteristics appear dominant because of the use of the above mentioned etch gas for the chemical etching process, one or both O₂ gas and N₂ gas is/are added as a passivation agent or a reaction inhibitor for suppressing the chemical etching characteristics.

Examples of the plasma etching apparatus for the plasma blanket etch-back process are an inductively coupled plasma (ICP) etching apparatus, an electron cyclotron resonance (ECR) etching apparatus, a microwave etching apparatus, and a capacitively coupled plasma etching process. The composition percentage of the etch gas, the source power, the bias power, the pressure and temperatures of the top electrode and bottom electrode are adjusted to control an etch profile of a substrate structure formed outside the openings 28 during the isolation of the lower electrodes.

FIG. 2C shows the aforementioned lower electrodes 29A formed by the lower electrode isolation process as illustrated in FIG. 2B. Herein, the lower electrodes 29A are a cylinder type.

Referring to FIG. 2D, a wet dip-out process is performed to remove the insulation layer 27. From this wet dip-out process, the cylindrical lower electrodes 29A are exposed.

In accordance with the preferred embodiment of the present invention, the plasma blanket etch-back process makes it possible to isolate the lower electrodes without generating punches at the bottom part of the lower electrodes even in the absence of the supplemental layer. This elimination of the supplemental layer provides the effect of preventing an incidence of single bit failure, thereby resulting in further increase in semiconductor device yields.

Also, since the etch process recipe is adjusted while the commonly used plasma etch apparatus is used, there is not a cost related burden for installing new apparatuses for forming the capacitors. Furthermore, simultaneous performance of the physical etching process having a characteristic of perpendicular directionality and the chemical etching process having an isotropic etching characteristic provides an additional effect on an improvement on etch uniformity.

While the present invention has been described with respect to certain preferred embodiments, it will be apparent to those skilled in the art that various changes and modifications may be made without departing from the spirit and scope of the invention as defined in the following claims.

1. A method for fabricating a semiconductor device, comprising:
forming an insulation layer with a plurality of openings on a substrate to form lower electrodes;
forming a conductive layer on the insulation layer; and
etching first portions of the conductive layer formed outside the openings in a faster rate than second portions of the conductive layer formed inside the openings, thereby obtaining the lower electrodes that are isolated from each other.

2. The method of claim 1, wherein the etching step uses a mixed gas of a first gas inducing a physical etching by being introduced in a substantially perpendicular direction to the substrate and a second gas inducing a chemical etching by being chemically reactive to the conductive layer in a plasma phase.

3. The method of claim 2, wherein an amount of the first gas is equal to that of the second gas.

4. The method of claim 2, wherein an amount of the first gas is less than that of the second gas.

5. The method of claim 3, wherein a percentage of the amount of the second gas ranges from approximately 1% to approximately 50%.

6. The method of claim 4, wherein a percentage of the amount of the second gas ranges from approximately 1% to approximately 50%.

7. The method of claim 2, wherein the mixed gas includes one of oxygen (O2) gas, nitrogen (N2) gas and a mixed gas of the O2 gas and the N2 gas.

8. The method of claim 1, wherein the etching step includes adjusting a bias power to cause the physical etching to occur less at an inner bottom part of each opening than at an outer part of each opening.

9. The method of claim 8, wherein the bias power is adjusted to be in a range from approximately 30 W to approximately 300 W.

10. The method of claim 2, wherein the first gas and the second gas are an inert gas and a chlorine-based gas, respectively when the conductive layer comprises TiN.

11. The method of claim 10, wherein the chlorine-based gas is one selected from a group consisting of Cl2, HCl and CCl4 and a combination thereof.

12. The method of claim 2, wherein when the conductive layer comprises a silicon-based material, the first gas is an inert gas; and the second gas is one selected from a group consisting of a fluorine-based gas, a chlorine-based gas, a bromine-based gas and a combination thereof.

13. The method of claim 12, wherein the fluorine-based gas include SF6, NF3 and CF4, and the chlorine-based gas and the bromine-based gas are Cl2 gas and HBr, respectively.

14. The method of claim 2, wherein the first gas and the second gas are an inert gas and a fluorine-based gas, respectively when the conductive layer comprises tungsten.

15. The method of claim 14, wherein the fluorine-based gas is one selected from a group consisting of SF6, NF3, CF4 and a combination thereof.

16. The method of claim 2, wherein when the conductive layer comprises a noble metal-based material, the first gas is an inert gas; and the second gas is one selected from a group consisting of O2 gas, Cl2 gas and a combination thereof.

17. The method of claim 1, wherein the etching step employs a plasma blanket etch-back process.

18. The method of claim 1, wherein at the etching step, a mixed gas of a first gas inducing a physical etching by being introduced in a substantially perpendicular direction to the substrate and a second gas inducing a chemical etching by being chemically reactive to the conductive layer in a plasma phase is used and a bias power is adjusted to cause the physical etching to occur less at an inner bottom part of each opening than an outer part of each opening.

19. The method of claim 18, wherein an amount of the first gas is equal to that of the second gas.

20. The method of claim 18, wherein an amount of the first gas is less than that of the second gas.

21. The method of claim 19, wherein a percentage of the amount of the second gas ranges from approximately 1% to approximately 50%.

22. The method of claim 20, wherein a percentage of the amount of the second gas ranges from approximately 1% to approximately 50%.

23. The method of claim 18, wherein the mixed gas is added with one of O2 gas, N2 gas and a mixed gas of the O2 gas and the N2 gas.

24. The method of claim 18, wherein the bias power is adjusted to be in a range from approximately 30 W to approximately 300 W.
